(19) United States
(12) Patent Application Publication
(10) Pub. No.: US 2006/0021870 A1
(43) Pub. Date: Feb. 2, 2006

(54) Profile detection and refurbishment of deposition targets

(75) Inventors: Kenneth Tsai, Emerald Hills, CA (US); Kenny King-Tai Ngan, Fremont, CA (US); Trung T. Doan, Los Gatos, CA (US)

Correspondence Address: APPLIED MATERIALS, INC.;Patent Department, M/S 2061, P.O. Box 450A, Santa Clara, CA, 95052, US

(73) Assignee: Applied Materials, Inc.

(21) Appl. No.: 10/900,532

(22) Filed: Jul. 27, 2004

(51) Int. Cl. C23C 14/00; C25B 13/00

(52) U.S. Cl. 204/192.13; 204/192.12; 204/298.03

(57) ABSTRACT

A method of refurbishing a deposition target having a surface with an eroded region involves measuring a depth profile of the eroded region. A target material is then provided to the eroded region in relation to the measured depth profile to refurbish the target by filling the eroded region with the target material. The process provides improved refurbishment of eroded target surfaces with higher refurbishing precision and less waste of valuable target material.

### BACKGROUND

The present invention relates to the refurbishment of sputtering targets used in substrate sputtering processes.

A sputtering chamber is used to sputter deposit material onto a substrate, such as for example integrated circuit chips and displays, to manufacture electronic circuits. Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the substrate. The sputtered material may be a metal, such as for example aluminum, copper, tungsten, titanium, cobalt, nickel or tantalum. The sputtered material may also be a metal compound, such as for example tantalum nitride, tungsten nitride or titanium nitride. In the sputtering processes, the sputtering target is bombarded by energetic ions formed in the energized gas, causing material to be knocked off the target and deposited as a film on the substrate. The sputtering chamber can also have a magnetic field generator that shapes and confines a magnetic field about the target to improve sputtering of the target material.

In these sputtering processes, certain regions of the target are often sputtered at higher sputtering rates than other regions resulting in uneven sputtering of the target surface. For example, uneven target sputtering can arise from the complex contoured magnetic field maintained about the target to confine or stir energized gas ions about the target surface. Uneven sputtering can also be related to differences in grain size or structure of the target material, chamber shape and geometry, and other factors. Uneven sputtering of the target forms sputtered depressions in the target such as pits, grooves, race-track like trenches, and other recesses, where material has been sputtered from the target at a higher rate than the surrounding areas. The formation of such depressions is undesirable because they can result in the deposition of a sputtered film having varying thickness on the substrate. Deep depressions and grooves in the target can also expose chamber components, such as backing plates, behind the target. Sputtering of material from the backing plate would contaminate the substrate being processed.

Accordingly, sputtered targets are typically used and removed from the chamber after the processing of a predefined number of substrates, before the depressions and groves formed on the target become too deep, wide or numerous. The partially used-up sputtering target is then discarded, or more typically, re-used when the target material is expensive or has a high purity level that is difficult to obtain. For example, the target can be re-used by melting down the sputtered target material and reshaping a new sputtering target. However, melting down and re-shaping the target is costly because as it requires fabrication of an entirely new target.

Several methods have also been developed to refurbish a sputtering target. In one method, the excessively sputtered regions of the target are filled with a powdered sputtering material, and a laser or electron beam is directed onto the powdered material to melt and bond the powdered material to the target, as for example described in U.S. patent application Ser. No. 2002/0112955 to Aimone et al, filed on Feb. 14, 2002, which is herein incorporated by reference in its entirety. In another method, the excessively sputtered regions of the target are filled with target material by arc spraying or arc welding methods that provide molten target material to the sputtered regions, as described by U.S. patent application Ser. No. 10/799,361 to Doan et al, filed on Mar. 12, 2004 and commonly assigned to Applied Materials, which is herein incorporated by reference in its entirety.

However, typical refurbishment processes may also overfill the sputtered regions or deposit target material on regions of the target that are adjacent to the sputtered regions, to ensure adequate fill of the sputtered regions. This can result in an uneven layer of the target material on the target surface, which is undesirable because the uniformity and evenness of the target surface is needed for good sputtering. To remedy this problem, the uneven target surface can be planarized, for example, by machining the target surface to form a flat surface. However, material machined from the target to planarize the target surface is often disposed of as waste, which is costly and potentially environmentally damaging, or may require a costly recycling process.

Thus, it is desirable to have a method of refurbishing a partially sputtered used target to fill in sputtered depression features formed in the target substantially without wasting excessive amounts of target material. It is further desirable to have a method of refurbishing a target that is not excessively costly and that can efficiently refurbish targets.

### SUMMARY

In one version, a method of refurbishing a deposition target having a surface that has an eroded region includes measuring a depth profile of the eroded region. Target material is provided to the eroded region in relation to the measured depth profile to fill the eroded region with the target material. The method may be used, for example, to refurbish grooves formed in the surface of sputtering target.

In a version of the refurbishing method, a surface profile that is an inverse of the depth profile is determined, and target material is provided to the eroded region in an amount that is sufficient to fill the eroded region with the target material and to form the surface profile.

A suitable target refurbishment apparatus has a target material delivery system to provide target material to the eroded region of the target. An apparatus controller has computer program code to control the target material delivery system, wherein the controller receives at least a portion of the measured depth profile of the eroded region and generates a signal in relation to the measured depth profile to control the target material delivery system to set the process parameters of the target material delivery system to provide material in the eroded regions in relation to the measured depth profile.

The target refurbishment apparatus can also have a profile detector to measure a depth profile of the eroded region and generate a first signal in relation to the depth profile, in addition to the target material delivery system. The controller receives a first signal from the profile detector relating to the depth profile of the eroded regions of the target, generates a second signal in relation to the first signal, and provides the second signal to the target material delivery system to set target delivery system parameters in relation to the measured depth profile.

### DRAWINGS

These features, aspects, and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1a is a schematic sectional side view of an embodiment of a deposition target having a surface with eroded regions formed therein;

FIG. 1b is a schematic sectional side view of an embodiment of a deposition target that has been at least partially refurbished;

FIG. 1c is a schematic sectional side view of another embodiment of a deposition target after a refurbishment process;

FIG. 1d is a schematic sectional side view of another embodiment of a deposition target after a refurbishment process, having a reverse image surface profile;

FIG. 2 is a schematic side view of an embodiment of a target refurbishment apparatus having a profile detector and a target material delivery system;

FIG. 3 is a sectional side view of an embodiment of a sputter deposition chamber having a refurbished target; and

FIG. 4 is a schematic view of computer program code for a refurbishment process.

### DESCRIPTION

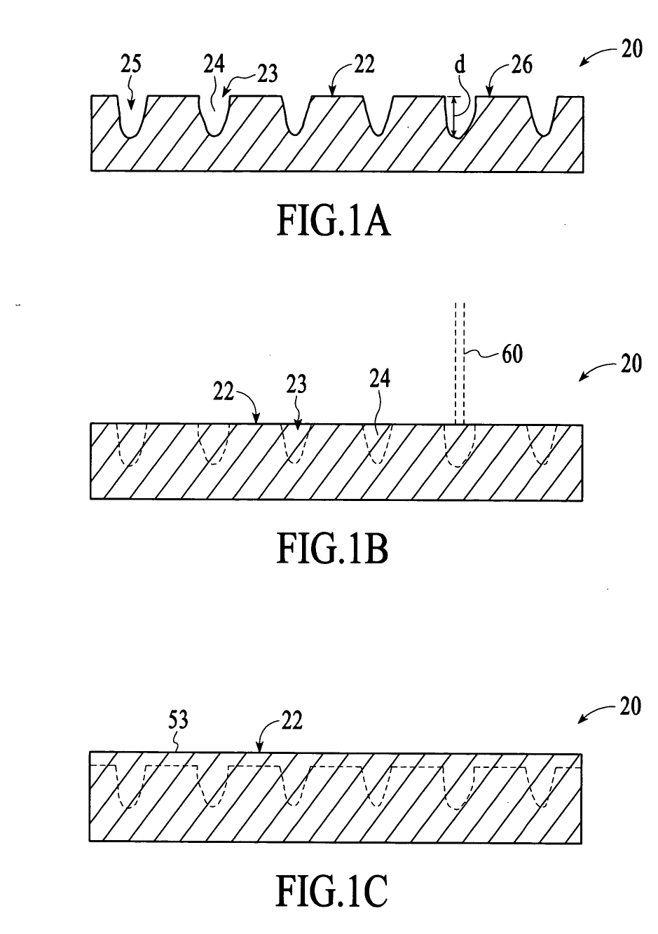

An embodiment of a target 20 capable of depositing material on a substrate 104 is shown in FIG. 1a. The target material can comprise a metal, such as for example at least one of titanium, aluminum, tantalum, tungsten, and copper, and can also comprise metals such as at least one of germanium, selenium and tellurium. The target 20 may have a surface 22 from which material has been removed to deposit the material on the substrate 104, as shown for example in Figure la. For example, the surface 22 can comprise a pre-sputtered surface that has been sputtered by energized gas ions to remove sputtering material from the surface 22. The surface 22 of the target can also have been used to deposit material on a substrate by another method. For example, an electromagnetic energy beam, such as a laser or electron beam, can be directed onto the surface to break material away from the surface 22.

In one version, the surface 22 comprises one or more eroded regions 23 that form as a result of removing material from the surface, for example by sputtering of material from that region 23 of the surface 22. In one version, the surface 22 comprises a sputtered depression 24 that is formed in the surface 22 as the result of, for example, uneven sputtering rates across the surface 22. For example, the sputtered depressions 24 can be grooves having multiple concentric rings 25, centered about the middle of the target 20. The target 20 can comprise from about 1 to about 6 of the rings 25, and the rings 25 can comprise depths in the target 20 of up to about 5 cm, such as about 3.5 cm, and can also comprise a width at the top of the ring of up to about 7.5 cm. The sputtered depressions 24 can also take other shapes and forms, such as pits, channels, holes or dish shaped depressions. The shape of the depressions 24 is dependent upon the target material, the shape and symmetry of the energy field applied to sputter or otherwise remove material from the target, and even the shape of any magnetic field applied across or from behind the target. Thus, the scope of the invention should not be limited to particular targets 20 or shapes of the depressions 24 formed in the targets 20.

A refurbishment process can be performed to refurbish the surface 22 of the target 20 and provide a fresh deposition surface 22. The refurbishment process can comprise providing fresh target material to the eroded regions 23 of the target 20 to replace material that has been sputtered away. For example, in one version, a refurbishment process comprises an electrical arc generating refurbishment process, as described for example in U.S. patent application Ser. No. 10/799,361 to Doan et al, filed on Mar. 12, 2004 which is herein incorporated by reference in its entirety. In an electrical arc generating process, such as an arc-spray or welding process, a consumable metal wire comprising the target material is inserted into an electrical arcing zone to at least partially liquefy the target material, and the molten target material is propelled by a pressurized gas towards the eroded region 23 of the target 20 to at least partially fill the region 23. Another version of a refurbishment process comprises a laser or electron beam assisted refurbishment process, as described for example in U.S. patent application Ser. No. 2002/0112955 to Aimone et al, published on Aug. 22, 2002, which is herein incorporated by reference in its entirety. The laser or electron beam assisted process can comprise filling the sputtered regions 23 with a precursor target material, such as a powdered target material, and heating the precursor material by directing an electromagnetic beam such as a laser or electron beam onto the precursor material to melt and bond the precursor target material to the target 20. Other refurbishment processes and apparatus, such as for example a flame-spraying process and apparatus, can also be used.

In one version, a depth profile of the target surface 22 is measured prior to, or concurrent with, refurbishment of the target 20. The depth profile is a measure of the height of the surface 22 at different points along the surface 22, and provides a measure of the topography and morphology of the surface 22. For example, the depth profile may comprise the height of various points along the eroded regions 23. In one version, the depth profile may comprise a measure of the extent d to which such points are depressed from a top surface 26 of the sputtering target 20, i.e., a depth of the points in the eroded region from a top surface 26. The depth profile may comprise a plurality of depths d across a surface cross-section, and may even comprise a three dimensional profile of the surface 22 having the depths d for a plurality of surface cross-sections, such as depths d at multiple different polar coordinates r (radius) and θ (angle) across the target surface 22. The depth profile desirably comprises a measure of the height of a sufficient number of points along the surface area of the surface 22, such that the depth profile provides a good measurement of the topography across the target surface 22, and especially in the eroded regions 23.

The depth profile of the target surface 22 can be measured by a method that provides information about the depth of the surface 22 at various points across the target surface. In one version, the depth profile is measured by a method that involves direct contact of a measuring device with the surface 22. For example, the depth profile can be measured by a profilometer comprising a needle or other stylus having a contacting surface that is passed over the target surface 22, and generates a depth profile comprising a trace of the fluctuations of the height of the surface 22. In another version, the depth profile is measure by a non-contacting method that is capable of determining the depth profile substantially without mechanically contacting the surface 22. For example, the depth profile can be measured by a profilometer or other device that is capable of detecting a property of radiation that is reflected from the surface at different points along the surface, such as an intensity of a wavelength of radiation. In one version, the depth profile can be measured by directing a laser beam onto the surface and detecting a property of the reflected radiation. For example, an interferometer can be used to scan the surface and determine the depth at various points along the surface 22. In another version, a property of a sound wave reflected from the surface 22 may be detected to determine the depth profile.

The depth profile can be used to tailor and improve the refurbishment process, by allowing for the selection of refurbishment parameters to provide target material to the target surface 22 in relation to the depth profile. For example, one or more of the amount and rate of target material provided to the surface 22 may be selected in relation to the depth profile, to provide improved refurbishment of the surface 22. Selecting the refurbishment parameters in relation to the depth profile can improve the target refurbishment because, for example, very deep or highly eroded regions 23 can be provided with more of the target material to at least partially fill the regions, whereas portions of the target 20 that are not as highly eroded, such as the top surface 26, may be provided with relatively less target material, since less material has been eroded from these areas. Accordingly, selecting the refurbishment parameters in relation to the depth profile allows target material to be provided to refurbish the eroded regions 23 with a sufficient amount of fresh target material, substantially without overfilling or underfilling the regions 23, as shown for example in FIG. 1b, wherein the dotted line indicates that boundary between the eroded regions 23 and the newly added target material. The target material can also be provided in relation to the depth profile such that the eroded regions 23 and even adjacent areas are filled to provide a substantially planar target surface 22. An added layer 53 of target material having a desired thickness may also be provided to replenish the target surface 22 with a sufficient amount of the target material, as shown in FIG. 1c.

In one version, the eroded regions 23 are filled with target material to provide a target surface 22 having a surface profile that is a reverse image of the depth profile, such as an inverse of the depth profile, as shown for example in FIG. 1d. The reverse image refurbished target surface 22a has a surface profile that is substantially opposite that of the sputtered surface 22b, and comprises a non-planar surface 22a having raised regions 28 of target material, such as raised rings, that overlie the former sputtered depressions 24, and lower regions 29 over areas of the target surface that were not as heavily eroded. The reverse image surface profile may be advantageous because it provides a greater thickness of target material in the regions of the target 20 that are demonstrably susceptible to erosion. Thus, the refurbished target 20 comprising the reverse image surface profile may be capable of being sputtered to process substrates substantially without forming excessive eroded regions 23 in the target 22, thereby increasing the processing lifetime of the target 22. In one version, the reverse image profile can be provided by calculating a thickness t of the target material that provides a refurbished surface 22a having the desired reverse image, from the depth profile of the sputtered surface 22b. For example, the thickness t can be calculated according to the equation (2*|d|)+c, where |d| is the absolute value of the depth d of a point on the sputtered surface 22b as measured from a top sputtered surface 26, and c is an offset value that can be constant across the target 20, and may be positive or negative number, or zero, according to the refurbished thickness of the target material that is desired. The desired refurbished thickness t is calculated for each desired point along the surface 22 of the target 20, and target material is then added in an amount that is sufficient to provide the desired thickness of material at each point and form a target surface 22 having the desired reverse image surface profile.

The depth profile of the surface 22 may also be measured or re-measured at any time during the refurbishment process. For example, an initial measurement of the depth profile may be made before refurbishing the target 20 with fresh target material, to obtain a measure of the erosion of the surface 22 at different points along the surface 22. The depth profile may then be re-measured during the refurbishment process, to check on the process, or to evaluate an amount or rate of target material being provided to the surface 22. The depth profile measurement may also be used to determine a refurbishment process endpoint. For example, depth profile measurement may determine a refurbishment process endpoint that is a point at which eroded regions 23 of the target have been substantially filled, and may also be when a substantially planar surface 22 of the target has been provided or when the desired reverse image surface profile has been formed.

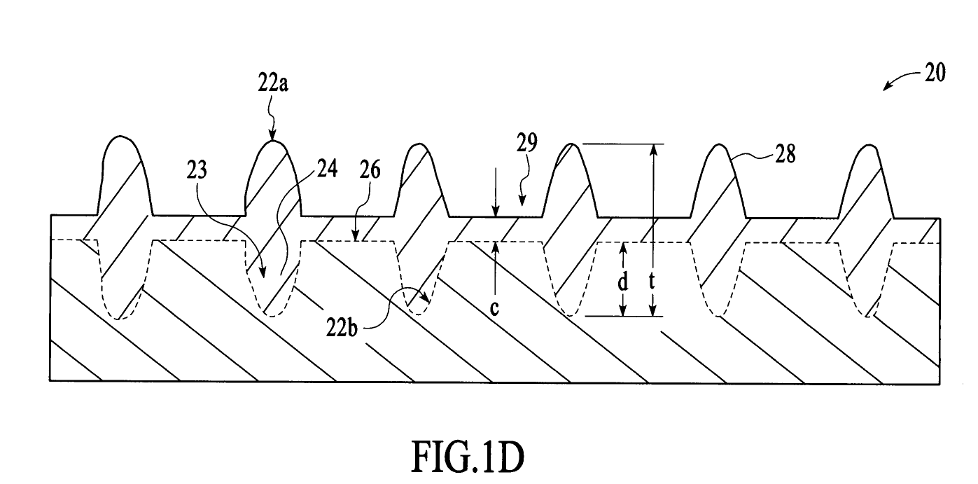

An example of a target refurbishment apparatus 52 capable of measuring a depth profile of a target surface 22 and providing target material to the surface 22 in relation to the depth profile is shown in FIG. 2. The target refurbishment apparatus 52 can comprise a profile detector 50 that is capable of measuring a depth profile of at least a portion of the target surface 22, such as the eroded regions 23. The profile detector 50 can comprise a surface detector that is capable of measuring the surface 22 by one or more of a contacting or non-contacting method, such as those described above. For example, the profile detector 50 may be capable of mechanically scanning the surface 22, such as with a scanning stylus. The profile detector 50 may also be capable of directing a probing beam onto the surface 22 and detecting a property of the reflected beam. For example, the profile detector 50 may be capable of directing one or more of a laser beam, electron beam and even sound waves onto the surface 22 and detecting a property of the reflected beam. The profile detector 50 is capable of measuring the depth profile and generating a signal in relation to the measured depth profile that can be used to set refurbishment process parameters. Suitable profile detectors 50 can comprise, for example, one or more of a profilometer, interferometer, ultrasonic sensor, optical detector, CCD laser sensor, laser tracker and laser profiler.

In another version, the target refurbishment apparatus 52 does not include a profile detector, but instead simply receives a signal that defines at least a portion of a depth profile of the eroded regions of a target, and operates the target material delivery system 56 in relation to the depth profile to fill the region defined by the profile. The depth profile of the target can be measured directly from the target being refurbished prior to or during the refurbishment process, estimated from studies done on a number of different targets that were used in the same process and chamber, or modeled from theoretical models based on empirical process factors such as erosion rates, pressure, magnetic field distribution, etc. A complete predetermined depth profile can also be stored in a memory of the apparatus and retrieved for processing a target.

The target refurbishment apparatus 52 also has a target material delivery system 56 capable of providing target material to the sputtered regions 23 of the target. For example, the target material delivery system 56 can comprise an electrical arc sprayer, such as for example, a twin wire arc sprayer or an arc welding device, as described for example in U.S. patent application Ser. No. 10/799,361 to Doan et al, filed on Mar. 12, 2004 which is herein incorporated by reference in its entirety. The target material delivery system 56 can also comprise a laser or electron beam assisted refurbisher, as described for example in U.S. patent application Ser. No. 2002/0112955 to Aimone et al, published on Aug. 22, 2002, which is herein incorporated by reference in its entirety. The target material delivery system 56 is desirably capable of providing target material to the surface 22 for the target in relation to the depth profile measure by the detector 50 to provide a desired and predetermined amount of target refurbishment. The target material delivery system 56 may be capable of scanning across the surface 22 of the target 20 to refurbish the target 20. The target refurbishment apparatus 52 may comprise a support (not shown) such as a clamp to hold the target 20 during refurbishment, and the support may also be moveable to position desired areas of the target surface 22 before the target material delivery system 56. Other target material delivery systems 56 suitable for providing fresh target material to refurbish the target 20 can also be used.

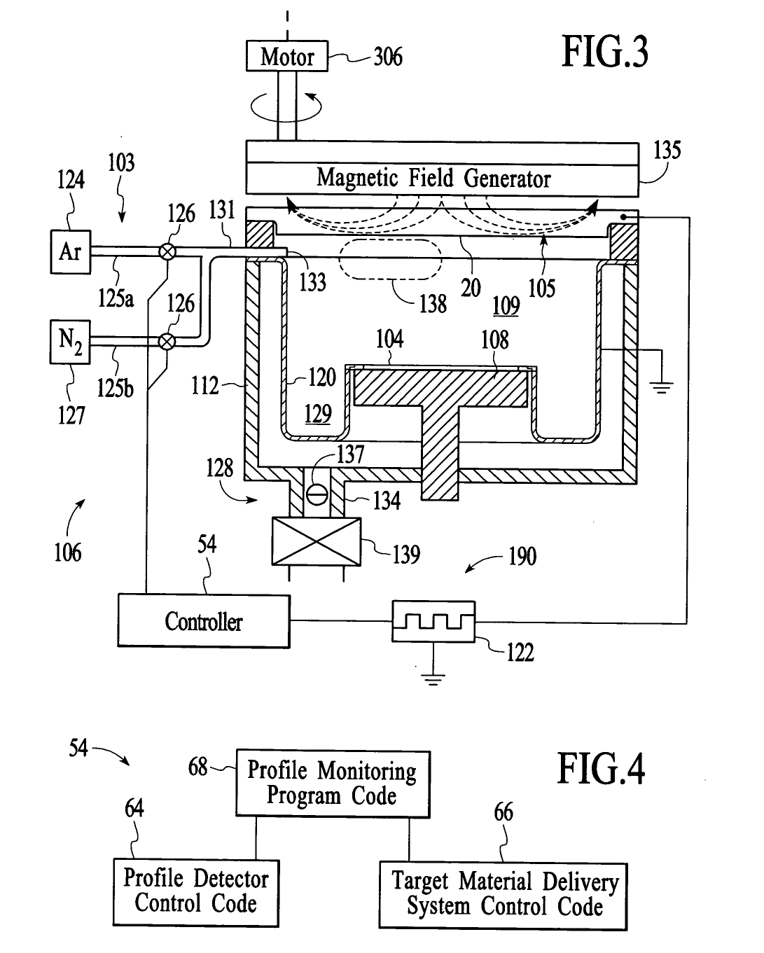

The target refurbishment apparatus 52 further comprises a controller 54 comprising computer program code to control the detector 50 and target material delivery system 56 to control refurbishment of the target 20, as shown for example in FIG. 4. The computer program code can comprise profile detector control code 64 to control the detector 50 to set detection parameters to measure a depth profile of the target surface 20. The detection parameters can include, for example, an area of the surface 20 scanned by the detector 50, detection error limits, a property of a probing beam, and a scanning duration. The computer program code can further comprise target material delivery system program code 66 to control the delivery system 56 and set refurbishment parameters for providing fresh target material to the surface 20. For example, the controller 54 can comprise program code to control, for example, the position of the delivery system 56 over the target surface 20, the rate at which fresh target material is provided at points on the surface 20, the amount of fresh target material provided, the composition of the target material, and the duration the target material delivery system 56 dwells at different points across the surface 22.

For example, for a target material delivery system 56 comprising an electrical arc sprayer, the controller 54 may comprise computer program code 66 to control at least one of an amount and composition of a consumable wire that is at least partially melted in the electrical arc, a pressure of a gas propelling the melted target material towards the surface 22, an electrical arcing voltage and power, and a duration the sprayer dwells over various point on the surface 22, as well as an angle and distance of the electrical arc sprayer from the surface 22 of the target 20. The controller 54 can thus provide a centralized control of the refurbishment process, including control of the depth profile detection as well as in providing fresh target material to the eroded regions 23. Furthermore, while the controller 54 is depicted as being separate from the profile detector 50 and delivery system 56 in FIG. 2, a portion of the controller 54 may also be housed in or share programming code with one or more of the detector 50 and delivery system 56.

The controller 54 further comprises profile monitoring program code 68 to set the target material delivery system parameters in relation to the measured depth profile. The profile monitoring program code 68 is adapted to receive a first signal from the profile detector 50 that is related to the detected depth profile of the target surface 22. The profile monitoring code 68 can then analyze the first signal to determine refurbishment parameters suitable for the measured profile. For example, the profile monitoring code 68 may calculate a difference between a desired thickness and an actual thickness of the target material at various points along the surface 22 of the target 20, and may determine an amount of fresh target material to be provided at each point to yield the desired final thickness of the target material. The profile monitoring code 68 may also calculate a volume of target material that is required to fill one or more eroded regions 23 to provide the desired thickness from the measured depth profile. The profile monitoring code 68 may furthermore determine a desired reverse image surface profile and calculate an amount of target material that is required at each point along the surface 22 to provide the desired profile.

The profile monitoring code 68 then generates a second signal in relation to the first signal and provides the second signal to the target delivery system 56 to set the target delivery system parameters to provide the desired refurbishment of the target 20. For example, the profile monitoring code 68 may generate one or more second signals that instruct the target delivery system 56 to set refurbishment parameters to provide more target material in severely eroded and relatively deep eroded regions 23, and less target material in regions that are not as severely eroded. As another example, the profile monitoring code 68 may generate one or more second signals that instruct the target delivery system 56 to set refurbishment parameters to provide target material to the target surface 22 in an amount sufficient to form a desired reverse image surface profile.

The profile monitoring program code 68 desirably sets the target material delivery system parameters with respect to the detected depth profile such that the eroded regions 23 are filled with fresh target material in a desired amount and rate, for example to form a substantially planar target surface 22, as shown for example in FIGS. 1b and 1c, or to form a non-planar target, as shown in FIG. 1d. For example, the profile monitoring code 68 may set the target material delivery system parameters to provide a volume of target material to the surface 22 that is calculated from the measured depth profile and that is sufficient to substantially fill the eroded regions 23 on the surface 22. The profile monitoring code 68 may also set the target material delivery system parameters to provide a volume and thickness of target material to the surface 22 that is calculated from the measured depth profile and that is sufficient to provide a desired reverse image surface profile. The profile monitoring code 68 may also be capable of determining an endpoint of the refurbishment process, and evaluating the progress of the refurbishment process. Thus, the controller 54 comprising the process monitoring control program code 68 is capable of controlling the profile detector 50 and target material delivery system 56 to control target refurbishment in relation to a measured depth profile of the target surface 22. The detection and control of the refurbishment process provide more accurate and precise refurbishment of the target surface, substantially without wasting excessive amounts of target material, while even allowing for the controlled formation of non-planar target surfaces 22.

Once the target surface 22 has been refurbished with the fresh target material, one or more subsequent treatment steps can be performed to prepare the target 20 for use in the sputtering chamber 106. For example, the surface 22 of the target can be exposed to an energy source to re-crystallize the metal material and provide a uniform sputtering surface 22. The energy source may be capable of heat treating the target material, for example by heating the target material to a temperature that is sufficiently high to re-orient misaligned crystals. The heat treating temperature may also desirably be kept below the melting point of the surface material. A suitable heat treatment temperature for the target 20 may be, for example, at least about 50° C. and even at least about 1000° C., such as from about 50° C. to about 3000° C., and even from about 50° C. to about 1000° C. In one version, the heat treatment step comprises heating the target 20 by directing heating radiation onto the surface 22 of the target 20, for example via overhead heating lamps. The target 20 can also be heated by placing a heater such as a resistive heater adjacent to the target, or by placing the target in a heating furnace. In another version, the heat treatment step comprises directing an electromagnetic energy beam 60, such as for example a laser beam, at the deposited metal on the target surface 22, as shown for example in FIG. 1b. The electromagnetic energy beam 60 rapidly heats the deposited material to re-orient the crystal structures in the material. The electromagnetic energy beam 60 can be scanned across the surface 22 of the target 20 to provide the heat treatment in the desired areas.

While the improved refurbishment method desirably provides a predetermined amount of target material to the surface 22, a machining step may also be performed to remove any non-uniformities from the target surface 22 or obtain a desired target thickness. The surface 22 of the target 20 can also be cleaned in a cleaning step to remove any residues remaining from one or more of the refurbishment, heat treatment, and machining steps. For example, the surface 22 can be cleaned by rinsing the surface 20 with a cleaning solvent, such as a solvent comprising isopropyl alcohol.

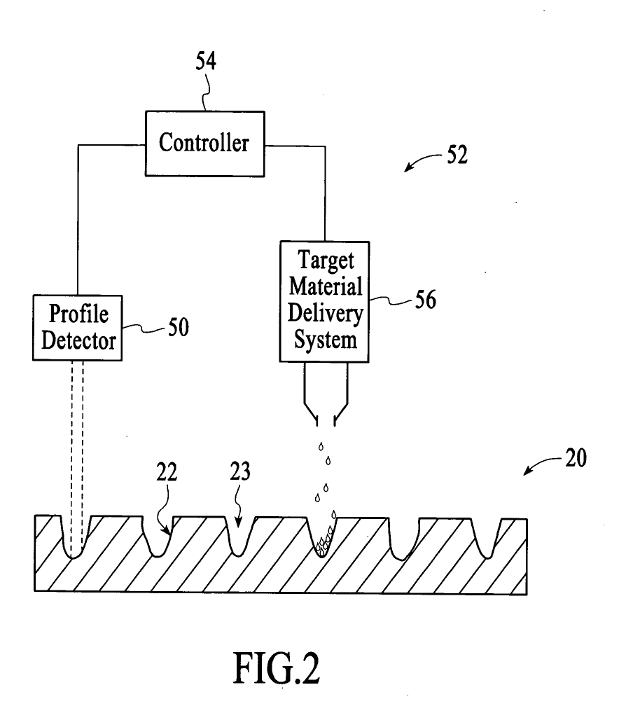

In one version, the target 20 can be used in a sputtering chamber, an embodiment of which is shown in FIG. 3, to sputter deposit a layer such as one or more of tantalum, tantalum nitride, aluminum, aluminum nitride, titanium, titanium nitride, tungsten, tungsten nitride and copper, on the substrate 104. A substrate support 108 is provided for supporting the substrate 104 in the chamber 106. The substrate 104 is introduced into the chamber 106 through a substrate loading inlet (not shown) in a sidewall of the chamber 106 and placed on the support 108. The support 108 can be lifted or lowered by support lift bellows (not shown) and a lift finger assembly (also not shown) can be used to lift and lower the substrate 104 onto the support 108 during transport of the substrate 104 into and out of the chamber 106.

A sputtering gas supply 103 introduces sputtering gas into the chamber 106 to maintain the sputtering gas at a sub atmospheric pressure in the process zone 109. The sputtering gas is introduced into the chamber 106 through a gas inlet 133 that is connected via the gas inputs 125a,b to one or more gas sources 124, 127, respectively. One or more mass flow controllers 126 are used to control the flow rate of the individual gases, which may be premixed in a mixing manifold 131 prior to their introduction into the chamber 106 or which may be separately introduced into the chamber 106. The sputtering gas typically includes a non-reactive gas, such as argon or xenon, that when energized into a plasma, energetically impinges upon and bombards the target 20 to sputter material, such as copper, titanium, titanium nitride, aluminum, tantalum, or tantalum nitride, off from the target 20. The sputtering gas may also comprise a reactive gas, such as nitrogen. Also, other compositions of sputtering gas that include other reactive gases or other types of non-reactive gases, may be used as would be apparent to one of ordinary skill in the art.

An exhaust system 128 controls the pressure of the sputtering gas in the chamber 106 and exhausts excess gas and by-product gases from the chamber 106. The exhaust system 128 comprises an exhaust port 129 in the chamber 106 that is connected to an exhaust line 134 that leads to one or more exhaust pumps 139. A throttle valve 137 in the exhaust line 134 may be used to control the pressure of the sputtering gas in the chamber 106. Typically, the pressure of the sputtering gas in the chamber 106 is set to sub-atmospheric levels.

The sputtering chamber 106 comprises a sputtering target 20 that facing the substrate 104 to deposit material on the substrate 104. The sputtering chamber 106 may also have a shield 120 to protect a wall 112 of the chamber 106 from sputtered material, and which may also serve as grounding plane. The target 20 can be electrically isolated from the chamber 106 and is connected to a power source 122, such as a DC or RF power source. In one version, the power source 122, target 20, and shield 120 operate as a gas energizer 190 that is capable of energizing the sputtering gas to sputter material from the target 20. The power source 122 can electrically bias the target 20 relative to the shield 120 to energize the sputtering gas in the chamber 106 to form a plasma that sputters material from the target 20. The material sputtered from the target 20 by the plasma is deposited on the substrate 104 and may also react with gas components of the plasma to form a deposition layer on the substrate 104.

The chamber 106 can further comprise a magnetic field generator 135 that generates a magnetic field 105 near the target 20 to increase an ion density in a high-density plasma region 138 adjacent to the target 20 to improve the sputtering of the target material. In addition, an improved magnetic field generator 135 may be used to allow sustained self-sputtering of copper or sputtering of aluminum, titanium, or other metals; while minimizing the need for non-reactive gases for target bombardment purposes, as for example, described in U.S. Pat. No. 6,183,614 to Fu, entitled “Rotating Sputter Magnetron Assembly”; and U.S. Patent No. 6,274,008 to Gopalraja et al., entitled “Integrated Process for Copper Via Filling,” both of which are incorporated herein by reference in their entirety. In one version, the magnetic field generator 135 generates a semi-toroidal magnetic field at the target 20. In another version, the magnetic field generator 135 comprises a motor 306 to rotate the magnetic field generator 135 about a rotation axis.

The chamber 106 can be controlled by the chamber controller 54, which comprises program code having instruction sets to operate components of the chamber 106 to process substrates 104 in the chamber 106. For example, the controller 54 can comprise a substrate positioning instruction set to operate one or more of the substrate support 108 and substrate transport to position a substrate 104 in the chamber 106; a gas flow control instruction set to operate the sputtering gas supply 103 and mass flow controllers 126; a gas pressure control instruction set to operate the exhaust system 128 and throttle valve 137 to maintain a pressure in the chamber 106; a gas energizer control instruction set to operate the gas energizer 190 to set a gas energizing power level; a temperature control instruction set to control temperatures in the chamber 106; and a process monitoring instruction set to monitor the process in the chamber 106.

Although exemplary embodiments of the present invention are shown and described, those of ordinary skill in the art may devise other embodiments which incorporate the present invention, and which are also within the scope of the present invention. For example, other materials other than the exemplary ones described herein can also be deposited. Additional cleaning steps can also be performed to clean the target. Also, targets having different shapes and compositions other than those specifically described can be refurbished. Furthermore, relative or positional terms shown with respect to the exemplary embodiments are interchangeable. Therefore, the appended claims should not be limited to the descriptions of the preferred versions, materials, or spatial arrangements described herein to illustrate the invention.

What is claimed is:

1. A method of refurbishing a deposition target having a surface comprising an eroded region, the method comprising:
(a) measuring a depth profile of the eroded region; and
(b) providing target material to the eroded region in relation to the measured depth profile to fill the eroded region with the target material.

2. A method according to claim 1 wherein (b) comprises providing a volume of target material to the eroded region that is calculated from the measured depth profile.

3. A method according to claim 1 wherein (b) comprises providing target material to the eroded region to form a surface profile that is an inverse of the measured depth profile.

4. A method according to claim 1 wherein (a) comprises measuring the depth profile of the eroded region with a profilometer.

5. A method according to claim 1 wherein (a) comprises measuring the depth profile of the eroded region by detecting a property of radiation reflected from the eroded region.

6. A method according to claim 1 wherein (b) comprises providing target material to the eroded region by at least partially melting a metal wire comprising the target material and propelling the molten target material towards the eroded region.

7. A method according to claim 1 wherein (b) comprises providing target material to the eroded region by providing a precursor material in the eroded region and heating the precursor material to bond to the target surface.

8. A method according to claim 7 wherein (b) comprises heating the precursor material by directing an electromagnetic energy beam at the target.

9. A method according to claim 1 wherein (b) comprises selecting a rate at which the target material is provided to the eroded region in relation to the depth profile.

10. A method according to claim 1 wherein (b) comprises selecting an amount of target material provided to the eroded region in relation to the depth profile.

11. A method according to claim 1 wherein a depth profile of the eroded region is measured while target material is being provided to the eroded groove.

12. A target refurbished according to the method of claim 1, the target having a substantially planar surface.

13. A method of refurbishing a deposition target having a surface comprising an eroded region, the method comprising:
(a) measuring a depth profile of the eroded region;
(b) determining a surface profile that is an inverse of the depth profile; and
(c) providing an amount of target material to the eroded region that is sufficient to fill the eroded region with the target material and form the surface profile.

14. A method according to claim 13 wherein (c) comprises providing target material to the eroded region by at least partially melting a metal wire comprising the target material and propelling the molten target material towards the eroded region.

15. A method according to claim 13 wherein (c) comprises providing target material to the eroded region by providing a precursor material in the eroded region and heating the precursor material to bond to the target surface.

16. A target refurbished according to the method of claim 13, the target having a non-planar surface.

17. A target refurbishment apparatus to refurbish a deposition target comprising a surface having an eroded region, the apparatus comprising:
(a) a target material delivery system to provide target material to the eroded region in relation to a depth profile of the eroded region; and
(b) a controller comprising computer program code to control the target material delivery system, wherein the controller receives at least a portion of the depth profile of the eroded region and generates a signal in relation to the depth profile to control the target material delivery system to set the process parameters of the target material delivery system to provide material in the eroded regions in relation to the depth profile.

18. An apparatus according to claim 17 wherein the computer program code is adapted to calculate a volume of target material to fill the eroded region, and wherein the controller is adapted to set process parameters of the target material delivery system to provide the volume of target material to the eroded region.

19. An apparatus according to claim 17 wherein the computer program code is adapted to determine a surface profile that is an inverse of the measured depth profile, and wherein the controller is adapted to set process parameters of the target material delivery system to provide target material to the eroded region to form the surface profile.

20. An apparatus according to claim 17 comprising a profile detector to measure a depth profile of the eroded region and generate a first signal in relation to the depth profile.

21. An apparatus according to claim 20 wherein the profile detector comprises a profilometer.

22. An apparatus according to claim 20 wherein the controller further comprises computer program code to receive and transmit signals to the profile detector.

23. An apparatus according to claim 20 wherein the profile detector is capable of detecting a property of radiation reflected from the eroded region.

24. An apparatus according to claim 17 wherein the target material delivery system comprises an electrical arc sprayer capable of generating an electrical arc to at least partially melt target material, and propelling the target material towards the target surface.

25. An apparatus according to claim 17 wherein the target delivery system is capable of providing target material in the eroded region and heating the precursor material to bond the target material to the target surface.

26. A target refurbishment apparatus to refurbish a deposition target comprising a surface having an eroded region, the apparatus comprising:
(a) a profile detector to measure a depth profile of the eroded region and generate a first signal in relation to the measured depth profile;
(b) a target material delivery system to provide target material to the eroded region; and
(c) a controller comprising computer program code to control the profile detector and target material delivery system, wherein the controller receives the first signal from the profile detector, generates a second signal in relation to the first signal, and provides the second signal to the target material delivery system to set target delivery system parameters in relation to the measured depth profile.

27. An apparatus according to claim 26 wherein the computer program code is adapted to calculate a volume of target material to fill the eroded region from the first signal, and wherein the controller is adapted to generate a second signal to set process parameters of the target material delivery system to provide the volume of target material to the eroded region.

28. An apparatus according to claim 26 wherein the computer program code is adapted to determine a surface profile that is an inverse of the measured depth profile, and wherein the controller is adapted to generate a second signal to set process parameters of the target material delivery system to provide target material to the eroded region to form the surface profile.

29. An apparatus according to claim 26 wherein the profile detector comprises a profilometer.

30. An apparatus according to claim 26 wherein the profile detector is capable of detecting a property of radiation reflected from the eroded region.

31. An apparatus according to claim 26 wherein the target material delivery system comprises an electrical arc sprayer capable of generating an electrical arc to at least partially melt target material, and propelling the target material towards the target surface.

32. An apparatus according to claim 26 wherein the target delivery system is capable of providing target material in the eroded region and heating the precursor material to bond the target material to the target surface.
